(19) United States
(12) Patent Application Publication
(10) Pub. No.: US 2021/0141137 A1
(43) Pub. Date: May 13, 2021

(54) OPTICAL MATERIAL, OPTICAL COMPONENT, AND APPARATUS

(71) Applicant: Yasuhiro KOIKE, Kanagawa (JP)

(72) Inventor: Yasuhiro KOIKE, Kanagawa (JP)

(21) Appl. No.: 16/635,894

(22) PCT Filed: Jul. 30, 2018
(86) PCT No.: PCT/JP2018/028497

§ 371 Date: Jan. 31, 2020

(30) Foreign Application Priority Data
Aug. 3, 2017 (JP) 2017-151091

(51) Int. Cl. G02B 5/30; G02B 1/02; G02F 1/13363

(52) U.S. Cl. CPC G02B 5/3083; G02F 1/13363; G02B 1/02

(57) ABSTRACT

An optical material includes: a medium that is transparent with respect to visible light; and a plurality of crystal materials having birefringence, the crystal materials being dispersed in the medium. The optical material is configured to randomize a polarization state of incident visible light, and emit visible light having a polarization degree lower than a polarization degree of the incident visible light.

### FIELD

The present invention relates to an optical material, an optical component, and an apparatus.

### BACKGROUND

In recent years, liquid crystal display devices (LCDs) are used as display devices for various apparatuses. For example, the liquid crystal display devices are used as a display device of a computer, a television receiver, an instrument panel and a navigation apparatus mounted on an automobile, an airplane, a ship, and the like, a personal digital assistant apparatus such as a smartphone, or digital signage (an electronic signboard) used for advertising or displaying a guide.

The liquid crystal display device causes an observer to visually recognize visual information such as an image or a picture by emitting light including display information from a display screen. In view of an operation principle thereof, the liquid crystal display device includes a liquid crystal layer and two polarizing plates that are disposed across the liquid crystal layer, a transmission polarizing direction of the polarizing plates being orthogonal to each other. Thus, light emitted from the display screen is typically linearly polarized light.

The liquid crystal display devices are used for various apparatuses as described above, so that observation may be performed through an optical apparatus having a polarization characteristic, for example, the display screen of the liquid crystal display device may be observed through polarizing sunglasses. In this case, brightness of the display screen visually recognized by the observer may be lowered as compared with a case of not using the polarizing sunglasses depending on an angle formed by a polarizing direction of emitted light and a transmission polarizing direction of the polarizing sunglasses. In a case in which the polarizing direction of the emitted light is orthogonal to the transmission polarizing direction of the polarizing sunglasses, the display screen cannot be visually recognized at all in some cases. Such a phenomenon is called a blackout.

To solve such a problem of lowering of visibility, there is disclosed a technique of disposing a phase difference plate (quarter-wave plate) to be closer to a visually recognizing side than the polarizing plate on the visually recognizing side in the liquid crystal display device, and converting linearly polarized light into circularly polarized light to be emitted from the display screen (refer to Patent Literature 1).

However, wavelength dependency (dispersion characteristic) of a phase difference on the phase difference plate is not considered in the technique disclosed in Patent Literature 1, so that there has been room for improvement to solve the problem of lowering of visibility. That is, the phase difference given to the light incident on the phase difference plate has wavelength dependency. Specifically, even with the phase difference plate that gives a phase difference of ¼ wavelength (that is, 7/2) to light of green color, for example, a phase difference given to light of another color in a visible light region, that is, light having a wavelength of red color or blue color is not ¼ wavelength due to the dispersion characteristic of the phase difference. The light having a wavelength the phase difference of which is not ¼ wavelength (that is, light that is not caused to be circularly polarized light) has transmittance with respect to the polarizing sunglasses that is different from the transmittance of light having a wavelength as circularly polarized light. As a result, when a display screen of a liquid crystal device using the technique disclosed in Patent Literature 1 is observed through the polarizing sunglasses, color irregularity may be caused on the display screen in some cases.

As another technique for solving the problem of lowering of visibility, there is disclosed a technique of disposing a polymer film having very high birefringence, that is, having very high retardation to be closer to a visually recognizing side than the polarizing plate on the visually recognizing side in the liquid crystal display device (refer to Patent Literature 2).

In the technique disclosed in Patent Literature 2, a liquid crystal display device using a white light emitting diode as a backlight light source has a configuration including a polymer film having retardation of a large value such as 3000 nm to 30000 nm disposed therein. Such a film is also called a super retardation film. Due to this, in a transmission spectrum of the two polarizing plates and the polymer film, the transmittance varies depending on the wavelength because of influence of interference caused by retardation of the polymer film. In the technique disclosed in Patent Literature 2, a period of variation of the transmittance is shortened by increasing retardation. A shape of an envelope spectrum of the varying transmission spectrum is then approximate to an emission spectrum of the white diode as a light source to improve visibility.

### CITATION LIST

### Patent Literature

Patent Literature 1: Japanese Patent Application Laid-open No. 2005-352068

Patent Literature 2: Japanese Patent Application Laid-open No. 2011-107198

### SUMMARY

### Technical Problem

However, there is also room for improvement for the technique disclosed in Patent Literature 2. That is, the technique disclosed in Patent Literature 2 is developed on the assumption that a light source having a relatively large emission spectrum is used such as a white light emitting diode in a format of fluorescent substance. Thus, in a case of what is called an RGB-LED combining light emitting diodes of red, green, and blue each having a relatively narrow spectrum width of emission spectrum to be used as the light source, visibility may be insufficiently improved in some cases. This is because, in a case in which a wavelength region having high transmittance in the transmission spectrum is deviated from an emission peak wavelength of the light emitting diode of any color, emission intensity of the light of the color from the liquid crystal display device is lowered, so that color irregularity and the like of the display screen are caused, and visibility is lowered. It is effective to shorten a wavelength period of variation in transmittance to prevent such wavelength deviation from being caused, but to shorten the wavelength period, retardation of the polymer film is required to be further increased. However, to further increase retardation, for example, the polymer film is required to be strongly drawn, which is hardly implemented. Furthermore, in a case of using a combination of red, green, and blue laser diodes as a light source, the spectrum width of each emission spectrum is further narrower than that in the case of the light emitting diode, so that the problem of wavelength deviation may be caused with higher possibility, and improvement in visibility becomes more insufficient in some cases.

The present invention has been made in view of such a situation, and provides an optical material that can improve visibility more preferably, and an optical component and an apparatus using the optical material.

### Solution to Problem

To solve the problem described above and to achieve the object, an optical material according to one aspect of the present invention includes: a medium that is transparent with respect to visible light; and a plurality of crystal materials having birefringence, the crystal materials being dispersed in the medium. The optical material is configured to randomize a polarization state of incident visible light, and emit visible light having a polarization degree lower than a polarization degree of the incident visible light.

In the optical material according to one aspect of the present invention, the crystal materials include crystal materials having different retardation with respect to the incident visible light.

In the optical material according to one aspect of the present invention, the crystal materials are dispersed in the medium in a state in which optical axes of the crystal materials are oriented in different directions.

In the optical material according to one aspect of the present invention, the crystal materials include crystal materials having different sizes.

In the optical material according to one aspect of the present invention, the crystal materials include a crystal material having a size equal to or larger than 0.1 μm and equal to or smaller than 100 μm.

In the optical material according to one aspect of the present invention, an absolute value of a difference between a refractive index of the medium and a refractive index of the crystal material is equal to or smaller than 0.2.

In the optical material according to one aspect of the present invention, a refractive index n₁ of the medium is a value between a refractive index nₒ of a normal light component of the crystal material and a refractive index nₑ of an abnormal light component of the crystal material.

In the optical material according to one aspect of the present invention, the medium includes a resin material.

In the optical material according to one aspect of the present invention, the medium has birefringence.

In the optical material according to one aspect of the present invention, the crystal material includes one or more of compounds selected from the group of calcium hydroxide, calcium carbonate, strontium carbonate, and graphite fluoride, and the medium includes one or more of compounds selected from the group of polyimide, polymethyl methacrylate, polycarbonate, polyethylene terephthalate, polyethylene naphthalate, polystyrene, triacetyl cellulose, and cycloolefin polymer.

An optical component according to one aspect of the present invention includes the optical material according to one aspect of the present invention.

The optical component according to one aspect of the present invention is an optical sheet.

In the optical component according to one aspect of the present invention, the optical sheet is placed in front of a display screen of a display device, or incorporated on a visually recognizing side of a polarizing plate of the display device.

In the optical component according to one aspect of the present invention, the optical sheet randomizes the polarization state of the incident visible light to prevent visibility of display from being lowered due to polarization dependence of the display device.

An apparatus according to one aspect of the present invention includes: the optical component according to one aspect of the present invention.

The apparatus according to one aspect of the present invention further includes: a display device having polarization dependence. The optical component randomizes the polarization state of the incident visible light to prevent visibility of display of the display device from being lowered due to the polarization dependence.

### Advantageous Effects of Invention

According to the present invention, an optical material randomizes a polarization state of incident visible light, and emits visible light having a polarization degree lower than a polarization degree of the incident visible light, so that visibility can be improved more preferably.

### BRIEF DESCRIPTION OF DRAWINGS

FIG. 1 is a schematic cross-sectional view of an optical sheet constituted of an optical material according to a first embodiment.

FIG. 2A is a diagram for explaining an example of a polarization state of emitted light in a case in which linearly polarized light having a wavelength in a visible light region is incident on a certain crystal material contained in the optical sheet illustrated in FIG. 1.

FIG. 2B is a diagram for explaining an example of a polarization state of emitted light in a case in which linearly polarized light having a wavelength in a visible light region is incident on a certain crystal material contained in the optical sheet illustrated in FIG. 1.

FIG. 3 is a diagram for explaining an example of a polarization state of emitted light in a case in which linearly polarized light having a wavelength in a visible light region is incident on the optical sheet illustrated in FIG. 1.

FIG. 4 is a diagram illustrating an effect of randomization of a polarization state performed by an optical sheet according to a first example.

FIG. 5 is a diagram illustrating an effect of randomization of a polarization state performed by an optical sheet according to a ninth example.

FIG. 6 is a diagram illustrating an effect of randomization of a polarization state performed by an optical sheet according to an eleventh example.

FIG. 7 is a schematic exploded perspective view of a main part of a liquid crystal display device according to a second embodiment.

FIG. 8 is a schematic exploded view of a main part of an organic EL display device according to a third embodiment.

### DESCRIPTION OF EMBODIMENTS

The following describes embodiments of the present invention in detail with reference to the drawings. The present invention is not limited to the embodiments. In the respective drawings, the same or corresponding elements are appropriately denoted by the same reference numeral. It should be noted that the drawings are schematic, and a relation between dimensions of respective elements and the like may be different from an actual relation. The relation or a ratio between dimensions may be different between the respective drawings.

### First Embodiment

FIG. 1 is a schematic cross-sectional view of an optical sheet constituted of an optical material according to a first embodiment. The optical sheet 1 includes a medium 1a, and a plurality of crystal materials 1b dispersed in the medium 1a.

The medium 1a has a transparent characteristic with respect to visible light. The visible light is light in a wavelength region the lower limit of which is 360 to 400 nm, and the upper limit of which is 760 to 830 nm in accordance with JIS Z8120:2001, for example. In the following description, the visible light may be simply referred to as light in some cases. It is sufficient that the medium 1a is transparent to a degree with which transmittance with respect to the visible light is equal to or larger than 50%. The transmittance is preferably equal to or larger than 80%, and more preferably equal to or larger than 90%.

The crystal material 1b is a single crystal or a polycrystal having a transparent characteristic with respect to the visible light, and has birefringence. As illustrated in FIG. 1, the crystal materials 1b include the crystal materials 1b having different shapes and sizes. Some of the crystal materials 1b are dispersed in the medium 1a in a state in which optical axes thereof are oriented in directions different from each other. However, some of the crystal materials 1b may have the same shape and the same size, and may have optical axes oriented in the same direction.

When visible light is incident on the optical sheet 1, the optical sheet 1 randomizes a polarization state of the incident visible light, and emits visible light the polarization degree of which is reduced to be lower than the polarization degree of the incident visible light. The polarization degree can be represented by a ratio between intensity I₀ of light that is emitted when light is incident on two polarizers the transmission polarizing directions of which are caused to be parallel, and intensity I₉₀ of light that is emitted when the same light is incident on two polarizers that are arranged in a cross Nicol state (I₉₀/I₀). This ratio takes a value between 0% to 100%, and as the ratio is larger, the polarization degree is assumed to be lower.

It is not necessarily clear why the optical sheet 1 randomizes the polarization state of the incident visible light and emits the visible light the polarization degree of which is reduced to be lower than the polarization degree of the incident visible light, but it can be considered that the reason thereof is based on the following principle. FIGS. 2A and 2B are diagrams for explaining an example of the polarization state of the emitted light at the time when linearly polarized light having a wavelength in a visible light region is incident on certain crystal materials 1ba and 1bb of the crystal materials 1b contained in the optical sheet 1. In this case, the crystal materials 1ba and 1bb are assumed to have different thicknesses in a traveling direction of pieces of linearly polarized light L11 and L12.

FIG. 2A illustrates a case in which the linearly polarized light L11 having a predetermined wavelength is incident on the crystal material 1ba. A polarization plane of the light L11 forms 45 degrees with respect to a y-axis and a z-axis on a y-z plane orthogonal to the traveling direction thereof. The light L11 is separated into a normal light component L11a of z-polarization and an abnormal light component L11b of y-polarization in the crystal material 1ba, and the normal light component L11a and the abnormal light component L11b travel in the crystal material 1ba by the same distance while sensing different refractive indexes, and are combined to be emitted. At this point, a phase difference is caused between the normal light component L11a and the abnormal light component L11b. In a case in which the phase difference is n/2, the crystal material 1ba functions as a quarter-wave plate for the light L11, and the light L11 incident on the crystal material 1ba is emitted as circularly polarized light L21.

On the other hand, FIG. 2B illustrates a case in which the light L12 having the same wavelength and the same polarizing direction as those of the light L11 is incident on the crystal material 1bb. The light L12 is separated into a normal light component L12a of z-polarization and an abnormal light component L12b of y-polarization in the crystal material 1bb, and the normal light component L12a and the abnormal light component L12b travel in the crystal material 1bb by the same distance while sensing different refractive indexes, and are combined to be emitted. At this point, a phase difference is caused between the normal light component L12a and the abnormal light component L12b. In a case in which the phase difference is π, the crystal material 1bb functions as a half-wave plate for the light L12, and the light L12 incident on the crystal material 1bb is emitted as linearly polarized light L22 orthogonal thereto.

That is, retardation with respect to the light L11 and retardation with respect to the light L12 are different between the crystal material 1ba and the crystal material 1bb. The crystal materials 1b contain crystal materials having different retardation with respect to the incident light as described above.

As described above, the medium 1a includes the crystal materials 1b having various shapes or various sizes, and the crystal materials 1b are dispersed in the medium 1a in a state in which the optical axes thereof are oriented in various directions. Additionally, retardation of each crystal material 1b with respect to the incident light is various. As a result, the pieces of light L11 and L12 having the predetermined wavelength described above are transmitted through the crystal material 1b to be emitted in various polarized state. The light L11 contains a component that is emitted without being transmitted through the crystal material 1b. Furthermore, the light L11 incident on one of the crystal materials 1b may be emitted and incident on the other one of the crystal materials 1b, but in this case, the light L11 is caused to be in a different polarized state by the other crystal material 1b to be emitted. Based on the principle as described above, the pieces of light L11 and L12 incident on the optical sheet 1 are considered to be emitted after the polarization states thereof are randomized.

Additionally, such randomization of the polarization state is not caused for light having a specific wavelength, and is caused for light having any wavelength in the visible light region.

FIG. 3 is a diagram for explaining an example of the polarization state of the emitted light in a case in which linearly polarized light L1 having a wavelength in the visible light region is incident on the optical sheet 1. The polarization plane of the light L1 forms 45 degrees with respect to the y-axis and the z-axis on the y-z plane orthogonal to the traveling direction thereof, and the light L1 contains various wavelength components in the visible light region. The light L1 is, for example, light emitted from the display screen of the liquid crystal display device.

When the light L1 is incident on the optical sheet 1, the optical sheet 1 randomizes the polarization state thereof, and emits light L2 containing light components having various polarization states such as linearly polarized light, elliptically polarized light (clockwise rotation, counterclockwise rotation), and circularly polarized light (clockwise rotation, counterclockwise rotation) as illustrated in an upper part of FIG. 3. Thus, the polarization degree of the light L2 becomes lower than the polarization degree of the light L1. FIG. 3 illustrates nine polarization states for the light L2, but these are merely representative polarization states. The light L2 does not necessarily include all of the polarization states, and may include another polarization state that is not illustrated herein.

In a case in which the observer directly observes the light L1 through the polarizing sunglasses, brightness of the light L1 visually recognized by the observer may be lowered as compared with a case without using the polarizing sunglasses depending on an angle formed by the polarizing direction of the light L1 and the transmission polarizing direction of the polarizing sunglasses. In a case in which the polarizing direction of the light L1 is orthogonal to the transmission polarizing direction of the polarizing sunglasses, a blackout phenomenon may be caused.

However, in a case in which the observer observes the light L1 through the polarizing sunglasses via the optical sheet 1, the observer visually recognizes the light L2. The polarization state of the light L2 is randomized, so that part of the light L2 is transmitted through the polarizing sunglasses even when the polarizing direction of the light L1 is orthogonal to the transmission polarizing direction of the polarizing sunglasses. As a result, the observer can visually recognize the light L2, so that the blackout phenomenon is prevented from being caused, and visibility is prevented from being lowered.

Additionally, as described above, randomization of the polarization state of the light L2 is not only caused for light having a specific wavelength but also caused for light of any wavelength in the visible light region. Due to this, color irregularity is prevented from being caused in the light L2 when being observed through the polarizing sunglasses, and visibility is prevented from being lowered.

As described above, by using the optical sheet 1 constituted of the optical material according to the first embodiment, visibility of the display device having a polarization characteristic such as a liquid crystal display device can be improved more preferably. The optical sheet 1 can be attached to the display screen of the display device to be used as a protective sheet.

Regarding the degree of lowering of the polarization degree by the optical sheet 1, the ratio (I₉₀/I₀) is preferably equal to or larger than 5%, more preferably equal to or larger than 10%, and even more preferably 100% so that the light L2 can be visually recognized even in a case in which the polarizing direction of the light L1 is orthogonal to the transmission polarizing direction of the polarizing sunglasses.

Preferable Characteristic

Next, the following describes a preferable characteristic of the optical sheet 1 constituted of the optical material according to the first embodiment.

First, the medium 1a is not limited so long as the medium 1a is made of a material having a transparent characteristic with respect to the visible light. For example, the material is a resin material such as polyimide (PI), polycarbonate (PC), polymethyl methacrylate (PMMA), polyethylene terephthalate (PET), polyethylene naphthalate (PEN), polystyrene (PS), triacetyl cellulose (TAC), cycloolefin polymer (COP), or other acrylic resins. PI is especially preferable because PI has high heat resistance, and has an exceptional mechanical characteristic, electrical characteristic, and chemical characteristic. These exemplified resin materials may be mixed in the medium 1a.

PI also has birefringence. However, the crystal material 1b exhibits an effect of randomization of the polarization state, so that it is expected that lowering of visibility depending on birefringence of the PI is prevented in a case of using PI as the medium 1a due to the above effect.

The crystal material 1b is not limited to an organic material or an inorganic material so long as the crystal material 1b is an anisotropic crystal that has a transparent characteristic with respect to the visible light and has birefringence. Examples of the inorganic material may include calcium hydroxide (Ca(OH)₂), calcium carbonate (CaCO₃), strontium carbonate (SrCO₃), or graphite fluoride (CF)ₙ. For example, calcium carbonate crystal, which is a crystal and has a spherical shape, can also be effectively used. Examples of the organic material may include a crystalline polymer such as a liquid crystal polymer. These exemplified crystal materials may be mixed in the crystal material 1b.

The crystal material 1b is preferably a material having a small refractive index difference from the medium 1a. This is because, if the refractive index difference between the crystal material 1b and the medium 1a is large, a phenomenon such as reflection, diffraction, and scattering may be caused at an interface between the crystal material 1b and the medium 1a, and the transmittance or a haze value of the optical sheet 1 may be lowered.

Herein, the refractive index of the medium 1a is assumed to be n₁, and the refractive index of the crystal material 1b is assumed to be n₂. n₂ is assumed to be an average value of a refractive index nₒ of the normal light component and a refractive index nₑ of the abnormal light component of the crystal material 1b. In view of suppression of Fresnel reflection, an absolute value of a difference between n₁ and n₂ is preferably equal to or smaller than 0.2, and is more preferably equal to or smaller than 0.1 in the visible light region. It is more preferable that n₁ is a value between nₒ and nₑ in the visible light region because the refractive index difference between the medium 1a and the crystal material 1b is small for both of the normal light component and the abnormal light component.

For example, at the wavelength of 589 nm in the vicinity of the center of the visible light region, the refractive index of the exemplified medium 1a is about 1.56 to 1.67 in a case of PT, about 1.57 to 1.59 in a case of PC, about 1.50 in a case of PMMA, about 1.57 in a case of PET, and about 1.59 in a case of PS. At the wavelength of 589 nm, the refractive index of the exemplified crystal material 1b is about 1.57 in any of the cases of calcium hydroxide, calcium carbonate, and strontium carbonate. The refractive index of the graphite fluoride is, for example, 1.543 to 1.544. Thus, these materials are preferable as a combination of the medium 1a and the crystal material 1b.

However, the relation between the refractive index of the medium 1a and the refractive index of the crystal material 1b is not limited thereto. This is because, even if the refractive index difference between the medium 1a and the crystal material 1b is large, the effect of randomization of the polarization state as described above may be caused when light is incident on the crystal material 1b. Thus, for example, when the optical sheet 1 satisfies desired transmittance or a desired haze value, the difference between the refractive index of the medium 1a and the refractive index of the crystal material 1b may be large to some degree.

Examples of other materials of the crystal material 1b include sodium sulfite, potassium chloride, calcium chloride, cesium chloride, sodium chloride, rubidium chloride, silicic acid, sodium acetate, yttrium oxide, zirconium oxide, magnesium oxide, potassium bromide, sodium bromide, potassium carbonate, sodium hydrogen carbonate, sodium carbonate, lithium carbonate, rubidium carbonate, calcium fluoride, aluminium oxide hydroxide, potassium iodide, di-lithium tetraborate, potassium sulphate, sodium sulfate, and barium sulfate. Preferably, by combining these crystal materials with a medium having a refractive index close to the refractive index of the crystal material, the optical material according to the embodiment of the present invention can be configured.

An upper limit of the size of the crystal material 1b is not limited in view of the principle of randomization of the polarized state. However, if the crystal material 1b is too large, the problem may be caused such that the crystal material 1b becomes visible, or flatness of the optical sheet 1 is lowered because the crystal material 1b is too large with respect to the thickness of the optical sheet 1, for example. In view of such a point, the size of the crystal material 1b is preferably equal to or smaller than 100 μm, and is more preferably equal to or smaller than 50 μm. In this case, the size of the crystal material 1b is, assuming that each particle of the crystal material 1b is a complete sphere or a rectangular parallelepiped, defined as a value corresponding to a diameter or a length of one side thereof.

A lower limit of the size of the crystal material 1b may be a value having retardation with respect to incident light. This value cannot be unconditionally defined because the value depends on birefringence of the crystal material 1b and the refractive index of the medium 1a around the crystal material 1b, but can be considered to be about 0.1 μm, by way of example. For example, in a case in which the thickness of the crystal material 1b is 1 μm and birefringence is 0.1, retardation is represented as 0.1×1 μm=100 nm. This value corresponds to ¼ wavelength of light of blue color having the wavelength of 400 nm. Thus, linearly polarized light is converted into circularly polarized light by the crystal material 1b. Considering a case in which the crystal materials 1b are stacked in a thickness direction of the optical sheet 1, even when the size of the crystal material 1b is an order of magnitude smaller than 1 μm, the same degree of depolarizing function can be given thereto. In view of the above description, an example of the lower limit is considered to be about 0.1 μm. Thus, by way of example, the crystal materials 1b preferably include the crystal material having the size equal to or larger than 0.1 μm and equal to or smaller than 100 μm.

Density of the crystal materials 1b in the medium 1a is not limited so long as randomization of the polarization state is caused to desired degree. For example, the density is 0.1 wt. % to 200 wt. %. Furthermore, it is preferable that the density is equal to or larger than 5 wt. % because randomization of the polarization state tends to be caused more uniformly in a plane of the optical sheet 1. In view of high transmittance, the density is preferably equal to or smaller than 30 wt. %. As exemplified above, regarding the degree of randomization of the polarization state, the ratio (I₉₀/I₀ is preferably equal to or larger than 5%, more preferably equal to or larger than 10%, and even more preferably 100%. Thus, the density of the crystal materials 1b may be adjusted so that a desired ratio (I₉₀/I₀ can be obtained in accordance with the characteristic of the medium 1a and the crystal material 1b.

In the optical sheet according to a modification of the first embodiment, a sheet-like medium may have a function of a quarter-wave plate or a super retardation film, and a plurality of crystal materials having birefringence may be dispersed in the medium. In this case, lowering of visibility such as a blackout is prevented by the function of the quarter-wave plate or the super retardation film of the medium, and lowering of visibility such as a blackout and color irregularity is additionally prevented by the function of randomization of the polarization state by the crystal material dispersed in the medium. That is, two types of effects of preventing visibility from being lowered can be obtained at the same time.

For example, in a case in which linearly polarized light having a certain wavelength in the visible light region is transmitted through an optical sheet constituted of a single medium, and the optical sheet gives a phase difference of ¼ wavelength thereto, the light having the certain wavelength is caused to be circularly polarized light, but light having a wavelength longer than or shorter than the certain wavelength is caused to be elliptically polarized light, for example. Thus, when an image emitted from a liquid crystal display device the screen of which is covered with the optical sheet constituted of the single medium is observed through the polarizing sunglasses, an amount of transmitted light of the polarizing sunglasses is different depending on the wavelength. As a result, color irregularity is caused on the display screen. However, with an optical sheet in which the crystal materials having birefringence are dispersed in a medium that gives the same phase difference of ¼ wavelength, the optical sheet randomizes the polarization state of the elliptically polarized light due to the effect of the crystal materials, so that color irregularity is prevented.

In a case of using the medium having the function of preventing visibility from being lowered as described above, the density of the crystal materials with respect to the medium can be considered to be lower than that in a case of using a medium not having the function of preventing visibility from being lowered. This is because the effect of preventing visibility from being lowered can be obtained to a certain degree due to the function of the medium, so that it can be considered that the crystal materials may have density to exhibit the function (mainly a function of preventing color irregularity) in a degree of compensating for the effect. The degree of the effect of the crystal materials may be appropriately adjusted depending on the density, the size, and the like of the crystal material.

Specifically, with a liquid crystal display device using a conventional LED having a continuous wide emission spectrum as a light source, rainbow irregularity and color irregularity can be settled by using a super retardation film having retardation of about 10000 nm, for example. However, in a case of a display device using organic EL, a quantum dot, or a laser beam as a light source that is expected to be developed, a shape of an emission spectrum of each color of RGB of the light source is sharpened. Thus, in a case of using the super retardation film, rainbow irregularity and color irregularity cannot be completely removed with retardation of 10000 nm, and retardation exceeding 30000 nm is required, which is not a realistic idea. In contrast, with the optical material according to the present invention, rainbow irregularity that cannot be completely removed with a conventional super retardation film can be prevented by randomizing the polarization state with a small amount (low density) of crystal materials, so that the optical material according to the present invention can also be applied to such a light source having the emission spectrum that has the sharpened shape.

### First to Eighth Examples

As first to eighth examples of the present invention, an optical sheet was prepared by performing the following procedure using PMMA or PS as a medium polymer, and using calcium carbonate as a crystal material.

First, calcite (NaRiKa Corporation, D20-1856-02) constituted of calcium carbonate the length of one side of which is about 3 cm to 4 cm was pulverized, and the pulverized calcite was put through a sieve to classify particles thereof into three types of crystal particles the length of one side of which was distributed in respective ranges from 0 μm to 25 μm, from 25 μm to 53 μm, and from 53 μm to 106 μm.

Subsequently, any one type of the classified crystal particles and a polymer pellet of PMMA (FUJIFILM Wako Pure Chemical Corporation, 138-02735) or PS (FUJIFILM Wako Pure Chemical Corporation) were put into a solvent of methylene chloride (FUJIFILM Wako Pure Chemical Corporation, 135-02446 (special grade reagent)) or ethyl acetate (FUJIFILM Wako Pure Chemical Corporation, 051-00351 (special grade reagent)), and the solvent was stirred with a shaker to completely dissolve the polymer to prepare a polymer solution. Mass of the crystal particles was any of 6 g, 30 g, 41 g, 60 g, 120 g, 156 g, and 200 g, mass of the polymer pellet was 1 g, and mass of the solvent was 4 g.

Subsequently, by using a knife coater set to have a height of 0.3 mm, the prepared polymer solution was spread in a sheet-like shape to be left standing on a horizontal glass plate the surface of which was silane-treated, and the solvent was evaporated. The sheet was then Laken off from the glass plate, and vacuum drying was performed at 90° C. for 24 hours to completely remove the solvent from the sheet. In this way, the optical sheet according to the first to the eighth examples was prepared. Table 1 indicates the polymer, the solvent, and the size of the crystal particle (the length of one side) used for preparation in the first to the eighth examples, and the density of the crystal particles in the prepared optical sheet.

TABLE 1

| | | | Size of | Density of |
|---|---|---|---|---|
| | | | crystal | crystals |
| No. | Polymer | Solvent | (μm) | (wt. %) |
| 1 | PMMA | Ethyl acetate | 0-25 | 60 |
| 2 | PMMA | Ethyl acetate | 25-53 | 156 |
| 3 | PMMA | Ethyl acetate | 53-106 | 200 |
| 4 | PMMA | Ethyl acetate | 0-25 | 6 |
| 5 | PMMA | Ethyl acetate | 0-25 | 30 |
| 6 | PMMA | Ethyl acetate | 0-25 | 120 |
| 7 | PMMA | Methylene | 0-25 | 41 |
| | | chloride | | |
| 8 | PS | Ethyl acetate | 0-25 | 60 |

The optical sheet according to the first example was placed on a surface of a liquid crystal display device using an RGB-LED backlight to be covered by an external polarizing plate, a white color picture was displayed by the liquid crystal display device, and an image at this time was photographed. A result thereof is illustrated in FIG. 4. In the left figure of FIG. 4, a region A1 is a region not including the optical sheet, and a region A2 is a region in which the optical sheet is placed. In this case, the external polarizing plate was placed to be in a cross Nicol state with respect to the polarizing plate disposed on a surface side (visually recognizing side) of the liquid crystal display device, so that a blackout was caused in the region A1 not including the optical sheet. On the other hand, in the region A2, the white color picture of the liquid crystal display device was visually recognized. This can be considered because the optical sheet randomizes the polarization state of linearly polarized light emitted from the liquid crystal display device, so that part of the emitted light is transmitted through the external polarizing plate to be visually recognized. FIG. 4 illustrates an image at the time when the optical sheet is rotated from the state illustrated in the left figure to the state illustrated in the right figure through the state illustrated in the middle figure. In any of the middle figure and the right figure in FIG. 4, the white color picture of the liquid crystal display device was visually recognized in the region in which the optical sheet was placed. This fact is considered to indicate that the optical sheet randomizes the polarization state sufficiently. Total light transmittance of the optical sheet according to the first example was measured by a Haze Meter (manufactured by NIPPON DENSHOKU INDUSTRIES CO., LTD., NDH2000), and a favorable value of 93% was obtained.

Similar experiments were performed by replacing the optical sheet according to the first example with optical sheets according to the second to the eighth examples. In all cases of using any of the optical sheets, the white color picture of the liquid crystal display device was visually recognized in the region in which the optical sheet was placed.

### Ninth and Tenth Examples, and First Comparative Example

As the ninth and the tenth examples, and a first comparative example of the present invention, an optical sheet was prepared by performing the following procedure using PMMA as a medium polymer, and using graphite fluoride as a crystal material.

First, 0.05 g (ninth example), 0.01 g (tenth example), or 0 g (first comparative example) of graphite fluoride having an average particle diameter of 5 μm and 0.95 g of polymer pellet of PMMA were put into 5 g of solvent of methylene chloride, and the solvent was stirred with a shaker to completely dissolve the polymer to prepare a polymer solution.

Subsequently, by using an applicator set to have a height of 0.5 mm, the prepared polymer solution was spread in a sheet-like shape to be left standing on a horizontal glass plate the surface of which was silane-treated, and the solvent was evaporated by natural drying. In this way, the optical sheets according to the second and the third examples, and the first comparative example were prepared. The density of graphite fluoride in the optical sheet according to the ninth and the tenth examples, and the first comparative example were 5 wt. %, 1 wt. %, and 0 wt. %, respectively.

The total light transmittance of the optical sheets according to the ninth and the tenth examples, and the first comparative example was measured by the Haze Meter, and favorable values of 94%, 92.7%, and 93.3% were obtained, respectively.

Display images were photographed in a case of placing the optical sheet according to the ninth example on part of a surface of a display screen of a tablet terminal (manufactured by Apple Inc.), and in a case of further covering the optical sheet with an external polarizing plate. A result thereof is illustrated in FIG. 5. The left figure of FIG. 5 indicates a photograph in a case of only placing the optical sheet on the surface of the display screen, but the region in which the optical sheet is placed is hardly discriminated because the transmittance of the optical sheet is good. On the other hand, in the right figure of FIG. 5, the display image is visually recognized only in the region in which a rectangular optical sheet is placed as a result of being covered by the external polarizing plate, and a blackout is caused in the other regions. This fact is considered to indicate that the optical sheet randomizes the polarization state sufficiently.

### Eleventh Example

As the eleventh example of the present invention, an optical sheet was prepared by performing the following procedure using PC as a medium polymer, and using calcium carbonate as a crystal material.

First, 1 g of polymer pellet of PC was put into 5 g of solvent of methylene chloride, and the solvent was stirred with a shaker to completely dissolve the polymer. Furthermore, 0.111 g of calcium carbonate (average particle diameter: 7.7 μm) was added thereto, the solvent was stirred with a stirrer, and ultrasonic waves were applied thereto for three minutes to prepare a polymer solution.

Subsequently, by using an applicator set to have a height of 0.5 mm, the prepared polymer solution was spread in a sheet-like shape to be left standing on a horizontal glass plate the surface of which was silane-treated, and the solvent was evaporated by natural drying. In this way, the optical sheet according to the eleventh example was prepared. The density of calcium carbonate in the optical sheet according to the eleventh example was 10 wt. %.

Display images were photographed in a case of placing the optical sheet according to the eleventh example on part of the surface of the display screen of the tablet terminal, and in a case of further covering the optical sheet with an external polarizing plate. A result thereof is illustrated in FIG. 6. The left figure of FIG. 6 indicates a photograph in a case of only placing the optical sheet on the surface of the display screen, but the region in which the optical sheet is placed is hardly discriminated because the transmittance of the optical sheet is good. On the other hand, in the right figure of FIG. 6, the display image is visually recognized only in the region in which the optical sheet, which has an arched shape that is partially cut out in a rectangular shape, is placed as a result of being covered by the external polarizing plate, and a blackout is caused in the other regions. This fact is considered to indicate that the optical sheet randomizes the polarization state sufficiently.

### Twelfth Example, and Second Comparative Example

As the twelfth example of the present invention, a phase difference sheet was prepared by drawing a resin material (PC) in which graphite fluoride is dispersed, and as the second comparative example, a phase difference sheet that is the same as an example X except that graphite fluoride is not dispersed was prepared. These phase difference sheets were placed on the surface of the liquid crystal display device and observed through the polarizing sunglasses, and it was found that color irregularity in display that was caused in a case of using the phase difference sheet according to the second comparative example was improved in a case of using the phase difference sheet according to the twelfth example.

### Second Embodiment

FIG. 7 is a schematic exploded perspective view of a main part of the liquid crystal display device according to a second embodiment. As illustrated in FIG. 7, a liquid crystal display device 100 has a configuration in which a backlight 101, a polarizing plate 102, a phase difference film 103, a glass substrate 104 with a transparent electrode, a liquid crystal layer 105, a glass substrate 106 with a transparent electrode, an RGB color filter 107, a phase difference film 108, a polarizing plate 109, and the optical sheet 1 according to the first embodiment are stacked in this order. That is, the liquid crystal display device 100 has a configuration obtained by incorporating the optical sheet 1 into a liquid crystal display device having a known configuration.

In the liquid crystal display device 100, the optical sheet 1 is incorporated on a visually recognizing side of the polarizing plate 109, that is, on the opposite side of the backlight 101. Thus, light emitted from the polarizing plate 109 is incident on the optical sheet 1, and is emitted after the polarization state thereof is randomized. As a result, with the liquid crystal display device 100, a blackout is not caused even when being observed through the polarizing sunglasses, color irregularity and the like are improved, and visibility is prevented from being lowered as compared with a case of not including the optical sheet 1.

### Third Embodiment

FIG. 8 is a schematic exploded view of a main part of an organic Electro Luminescence (EL) display device according to a third embodiment. As illustrated in FIG. 8, an organic EL display device 200 has a configuration in which a glass substrate 201, a reflective electrode 202, an organic EL layer 203, a transparent electrode 204, a glass substrate 205, a circularly polarizing plate 206 including a quarter-wave plate 206a and a polarizing plate 206b, and a cover layer 207 including a cover film 207a and a hard coat layer 207b are stacked in this order. The organic EL display device 200 also includes the optical sheet 1 according to the first embodiment that is disposed to envelop the cover layer 207. That is, the organic EL display device 200 has a configuration obtained by incorporating the optical sheet 1 into an organic EL display device having a known configuration.

In the organic EL display device 200, the circularly polarizing plate 206 is disposed to prevent light incident from the outside from being reflected by the reflective electrode 202 to be output from the display screen. That is, as illustrated in FIG. 8, when unpolarized light L10 is incident from the outside, first, the polarizing plate 206b transmits only linearly polarized light in a specific direction. A phase difference of π/2 is given to the linearly polarized light transmitted through the polarizing plate 206b by the quarter-wave plate 206a, and the linearly polarized light is converted into circularly polarized light. The phase difference of π/2 is further given to the circularly polarized light by the quarter-wave plate 206a after the circularly polarized light is reflected by the reflective electrode 202, and the circularly polarized light is converted into linearly polarized light the polarizing direction of which is orthogonal to that of the linearly polarized light transmitted through the polarizing plate 206b. As a result, the linearly polarized light is absorbed by the polarizing plate 206b, so that the problem that the light incident from the outside is reflected by the reflective electrode 202 to be output from the display screen is solved.

Additionally, in the organic EL display device 200, the optical sheet 1 is incorporated on a visually recognizing side of the polarizing plate 206b, that is, on the opposite side of the reflective electrode 202. Thus, light configuring an image or a picture emitted from the polarizing plate 206b is incident on the optical sheet 1, and is emitted after the polarization state thereof is randomized. As a result, with the organic EL display device 200, a blackout is not caused even when being observed through the polarizing sunglasses, color irregularity and the like are improved, and visibility is prevented from being lowered as compared with a case of not including the optical sheet 1.

In this way, by randomizing the polarization state of the incident light, the optical sheet 1 prevents visibility of display from being lowered due to polarization dependence for a display device having the polarization dependence such as the liquid crystal display device 100 and the organic EL display device 200.

By being combined with various apparatuses including a liquid crystal display device, an organic EL display device, and the like such as a navigation apparatus and a personal digital assistant apparatus, the optical sheet 1 can prevent visibility of display from being lowered due to polarization dependence of the display device.

In the second and the third embodiments, the optical sheet according to the modification of the first embodiment may be used in place of the optical sheet 1 according to the first embodiment. In the embodiments and the modifications thereof described above, the optical material constitutes the optical sheet as a sheet-like optical component, but the shape of the optical component constituted of the optical material is not limited. The optical component may have various shapes such as a film shape, a rod shape, and a bulk shape. By combining such optical components having various shapes with a display device having polarization dependence, it is possible to prevent visibility of display from being lowered due to polarization dependence of the display device.

The method of preparing the optical material according to the present invention is not limited to the preparation method of forming the optical material in a sheet-like shape on the glass plate by using a knife coater and the like as described in the above example, and the optical material according to the present invention can be prepared by various preparation methods. For example, the optical material according to the present invention may be prepared as a coating layer by applying a solution to a base material to be solidified. The optical material according to the present invention may also be prepared as an adhesive material, so that the adhesive material may be attached to various optical components and the like to be used. As described above, the optical material and the optical component according to the present invention may have various shapes, and can be prepared by using various shaping methods. That is, the optical material and the optical component according to the present invention can be prepared by appropriately selecting a preferred preparation method depending on a shape, a material characteristic, a use mode, and the like of the optical material and the optical component.

The present invention is not limited to the embodiments described above. The present invention encompasses a configuration obtained by appropriately combining the constituent elements described above. Additional effects and modifications are easily conceivable by those skilled in the art. Thus, a more extensive aspect of the present invention is not limited to the embodiments described above, and can be variously modified.

### REFERENCE SIGNS LIST

1 OPTICAL SHEET
1a MEDIUM
1b, 1ba, 1bb CRYSTAL MATERIAL
100 LIQUID CRYSTAL DISPLAY DEVICE
101 BACKLIGHT
102, 109, 206b POLARIZING PLATE
103, 108 PHASE DIFFERENCE FILM
104, 106 GLASS SUBSTRATE WITH TRANSPARENT ELECTRODE
105 LIQUID CRYSTAL LAYER
107 RGB COLOR FILTER
200 ORGANIC EL DISPLAY DEVICE
201, 205 GLASS SUBSTRATE
202 REFLECTIVE ELECTRODE
203 ORGANIC EL LAYER
204 TRANSPARENT ELECTRODE
206 CIRCULARLY POLARIZING PLATE
206a QUARTER-WAVE PLATE
207 COVER LAYER
207a COVER FILM
207b HARD COAT LAYER
A1, A2 REGION
L1, L10, L11, L12, L2, L21, L22 LIGHT
L11a, L12a NORMAL LIGHT COMPONENT
L11b, L12b ABNORMAL LIGHT COMPONENT

1. An optical material comprising:
a medium that is transparent with respect to visible light; and
a plurality of crystal materials having birefringence, the crystal materials being dispersed in the medium, wherein
the optical material is configured to randomize a polarization state of incident visible light, and emit visible light having a polarization degree lower than a polarization degree of the incident visible light.

2. The optical material according to claim 1, wherein the crystal materials include crystal materials having different retardation with respect to the incident visible light.

3. The optical material according to claim 2, wherein the crystal materials are dispersed in the medium in a state in which optical axes of the crystal materials are oriented in different directions.

4. The optical material according to claim 2, wherein the crystal materials include crystal materials having different sizes.

5. The optical material according to claim 1, wherein the crystal materials include a crystal material having a size equal to or larger than 0.1 μm and equal to or smaller than 100 μm.

6. The optical material according to claim 1, wherein an absolute value of a difference between a refractive index of the medium and a refractive index of the crystal material is equal to or smaller than 0.2.

7. The optical material according to claim 6, wherein a refractive index n1 of the medium is a value between a refractive index no of a normal light component of the crystal material and a refractive index ne of an abnormal light component of the crystal material.

8. The optical material according to claim 1, wherein the medium includes a resin material.

9. The optical material according to claim 1, wherein the medium has birefringence.

10. The optical material according to claim 1, wherein the crystal material includes one or more of compounds selected from the group of calcium hydroxide, calcium carbonate, strontium carbonate, and graphite fluoride, and the medium includes one or more of compounds selected from the group of polyimide, polymethyl methacrylate, polycarbonate, polyethylene terephthalate, polyethylene naphthalate, polystyrene, triacetyl cellulose, and cycloolefin polymer.

11. An optical component comprising:
the optical material according to claim 1.

12. The optical component according to claim 11, wherein the optical component is an optical sheet.

13. The optical component according to claim 12, wherein the optical sheet is placed in front of a display screen of a display device, or incorporated on a visually recognizing side of a polarizing plate of the display device.

14. The optical component according to claim 13, wherein the optical sheet randomizes the polarization state of the incident visible light to prevent visibility of display from being lowered due to polarization dependence of the display device.

15. An apparatus, comprising:
the optical component according to claim 11.

16. The apparatus according to claim 15, further comprising:
a display device having polarization dependence, wherein
the optical component randomizes the polarization state of the incident visible light to prevent visibility of display of the display device from being lowered due to the polarization dependence.
